(19) United States
(12) Patent Application Publication
(10) Pub. No.: US 2022/0199928 A1
(43) Pub. Date: Jun. 23, 2022

(54) ORGANIC ELECTROLUMINESCENT DEVICE, DISPLAY PANEL AND DISPLAY DEVICE

(71) Applicant: BOE Technology Group Co., Ltd., Beijing (CN)

(72) Inventors: Juanjuan YOU, Beijing (CN); Huaiting SHIH, Beijing (CN); Changyen WU, Beijing (CN); Yongqi SHEN, Beijing (CN); Bin Bu, Beijing (CN); Wenfeng SONG, Beijing (CN); Linlin WANG, Beijing (CN)

(21) Appl. No.: 17/271,677

(22) PCT Filed: Jun. 28, 2020
(86) PCT No.: PCT/CN2020/098618

§ 371 Date: Feb. 26, 2021

(30) Foreign Application Priority Data
Aug. 30, 2019 (CN) 201910817652.7

(51) Int. Cl. H01L 51/50

(52) U.S. Cl. CPC H01L 51/5004; H01L 51/5092; H01L 51/5072; H01L 51/5056

(57) ABSTRACT

The present disclosure provides an organic electroluminescent device, a display panel and a display device, including a first electrode, a first light-emitting layer, a first electron transport layer, an N-type charge generation layer, a P-type charge generation layer, a first hole transport layer, a second light-emitting layer and a second electrode that are stacked; where the N-type charge generation layer includes a host electron transport material and a first guest electron transport material having a set matching energy level there between.

### CROSS REFERENCES TO RELATED APPLICATIONS

The present disclosure claims priority to Chinese patent application No. 201910817652.7, entitled “ORGANIC ELECTROLUMINESCENT DEVICE, DISPLAY PANEL AND DISPLAY DEVICE”, filed with the Chinese Patent Office on Aug. 30, 2019. The disclosure of the above application is incorporated herein by reference in its entirety.

### FIELD

The present disclosure relates to the technical field of display, and in particular to an organic electroluminescent device (OLED), a display panel and a display device.

### BACKGROUND

In order to meet requirements for high-quality display, high resolution is the main direction in the future. The side-by-side mode requires precise positioning of the fine metal mask (FMM) and thus is not suitable for fabrication of ultra-high resolution products, while a mode of integrating a white light organic electroluminescent device (WOLED) with a color filter (CF) is a better choice. In addition, it is also easier to meet requirements for high efficiency and a long service life by the use of a tandem white light organic electroluminescent device (Tandem WOLED).

### SUMMARY

An OLED provided by an embodiment of the present disclosure includes a first electrode, a first light-emitting layer, a first electron transport layer, an N-type charge generation layer, a P-type charge generation layer, a first hole transport layer, a second light-emitting layer and a second electrode that are stacked;

where the N-type charge generation layer includes a host electron transport material and a first guest electron transport material; and the host electron transport material and the first guest electron transport material have a set matching energy level therebetween.

In a possible implementation manner, in the OLED provided by the embodiment of the present disclosure, an HOMO value of either of the host electron transport material and the first guest electron transport material is less than or equal to −6.0 eV; and an absolute value of a difference between an LUMO value of the host electron transport material and an LUMO value of the first guest electron transport material is greater than or equal to 0.2 eV.

In a possible implementation manner, the OLED provided by the embodiment of the present disclosure further includes a buffer layer positioned between the N-type charge generation layer and the first electron transport layer;

where the buffer layer includes a second guest electron transport material.

In a possible implementation manner, in the OLED provided by the embodiment of the present disclosure, an LUMO value of the second guest electron transport material is greater than or equal to the LUMO value of the host electron transport material and is less than or equal to an LUMO value of the first electron transport layer; and a difference between the LUMO value of the first electron transport layer and the LUMO value of the second guest electron transport material is less than or equal to 0.3 eV.

In a possible implementation manner, in the OLED provided by the embodiment of the present disclosure, the P-type charge generation layer includes a first P-type charge generation layer, a second hole transport layer and a second P-type charge generation layer that are stacked; and the first P-type charge generation layer and the N-type charge generation layer are adjacent, and the second P-type charge generation layer and the first hole transport layer are adjacent.

In a possible implementation manner, in the OLED provided by the embodiment of the present disclosure, the first P-type charge generation layer includes a first hole transport material doped with a first Lewis acid, and a mass percent of the first Lewis acid in the first P-type charge generation layer is 5%-15%;

the second P-type charge generation layer includes a second hole transport material doped with a second Lewis acid, and a mass percent of the second Lewis acid in the second P-type charge generation layer is 1%-5%; and

an absolute value of an HOMO value of the second hole transport layer is less than or equal to 5.5 eV.

In a possible implementation manner, in the OLED provided by the embodiment of the present disclosure, the mass percent of the first Lewis acid in the first P-type charge generation layer is 10%;

the mass percent of the second Lewis acid in the second P-type charge generation layer is 3%; and

the absolute value of the HOMO value of the second hole transport layer is less than or equal to 5.3 eV.

In a possible implementation manner, the OLED provided by the embodiment of the present disclosure further includes a third hole transport layer, a second electron transport layer, and an electron injection layer;

where the first electrode, the third hole transport layer, the first light-emitting layer, the first electron transport layer, the N-type charge generation layer, the P-type charge generation layer, the first hole transport layer, the second light-emitting layer, the second electron transport layer, the electron injection layer, and the second electrode are stacked in sequence.

In a possible implementation manner, the OLED provided by the embodiment of the present disclosure further includes a third hole transport layer, a second electron transport layer and an electron injection layer;

where the first electrode, the third hole transport layer, the first light-emitting layer, the first electron transport layer, the buffer layer, the N-type charge generation layer, the P-type charge generation layer, the first hole transport layer, the second light-emitting layer, the second electron transport layer, the electron injection layer and the second electrode are stacked in sequence.

In a possible implementation manner, the OLED provided by the embodiment of the present disclosure further includes a third hole transport layer, a second electron transport layer, and an electron injection layer;

where the first electrode, the third hole transport layer, the first light-emitting layer, the first electron transport layer, the N-type charge generation layer, the first P-type charge generation layer, the second hole transport layer, the second P-type charge generation layer, the first hole transport layer, the second light-emitting layer, the second electron transport layer, the electron injection layer, and the second electrode are stacked in sequence;

or, the first electrode, the third hole transport layer, the first light-emitting layer, the first electron transport layer, the buffer layer, the N-type charge generation layer, and the P-type charge generation layer, the second hole transport layer, the second P-type charge generation layer, the first hole transport layer, the second light-emitting layer, the second electron transport layer, the electron injection layer and the second electrode are stacked in sequence.

In a possible implementation manner, in the OLED provided by the embodiment of the present disclosure, the first light-emitting layer and the second light-emitting layer emit light with a same color or different colors.

According to another aspect, embodiments of the present disclosure further provide another OLED, which includes a first electrode, a first light-emitting layer, a first electron transport layer, an N-type charge generation layer, a P-type charge generation layer, a first hole transport layer, a second light-emitting layer and a second electrode that are stacked;

where the P-type charge generation layer includes a first P-type charge generation layer, a second hole transport layer, and a second P-type charge generation layer that are stacked; the first P-type charge generation layer and the N-type charge generation layer are adjacent; and the second P-type charge generation layer and the first hole transport layer are adjacent.

In a possible implementation manner, in the OLED provided by the embodiment of the present disclosure, the first P-type charge generation layer includes a first hole transport material doped with a first Lewis acid, and a mass percent of the first Lewis acid in the first P-type charge generation layer is 5%-15%;

the second P-type charge generation layer includes a second hole transport material doped with a second Lewis acid, and a mass percent of the second Lewis acid in the second P-type charge generation layer is 1%-5%; and

an absolute value of an HOMO value of the second hole transport layer is less than or equal to 5.5 eV.

In a possible implementation manner, in the OLED provided by the embodiment of the present disclosure, the mass percent of the first Lewis acid in the first P-type charge generation layer is 10%;

the mass percent of the second Lewis acid in the second P-type charge generation layer is 3%; and

the absolute value of the HOMO value of the second hole transport layer is less than or equal to 5.3 eV.

In a possible implementation manner, the OLED provided by the embodiment of the present disclosure further includes a third hole transport layer, a second electron transport layer and an electron injection layer;

where the first electrode, the third hole transport layer, the first light-emitting layer, the first electron transport layer, the N-type charge generation layer, the first P-type charge generation layer, the second hole transport layer, the second P-type charge generation layer, the first hole transport layer, the second light-emitting layer, the second electron transport layer, the electron injection layer, and the second electrode are stacked in sequence.

According to another aspect, an embodiment of the present disclosure further provides a display panel including the above OLEDs.

According to another aspect, an embodiment of the present disclosure further provides a display device including the above display panels.

### BRIEF DESCRIPTION OF THE DRAWINGS

FIGS. 1-4 are respectively structural schematic diagrams of OLEDs according to embodiments of the present disclosure.

### DETAILED DESCRIPTION OF THE EMBODIMENTS

The Tandem WOLED is to fabricate OLEDs by depositing overlapping layers between the cathode and the anode without using the FMM, i.e., depositing different materials in a vacuum state to sequentially form organic functional layers including organic light-emitting layers. Besides, the Tandem WOLED includes a plurality of organic light-emitting layers emitting respectively light beams with different colors; a charge generation layer is arranged between two adjacent organic light-emitting layers; and holes and electrons are separated in the charge generation layer and injected into the adjacent organic light-emitting layers. Since efficiency of charge separation and ability of injection into the adjacent organic light-emitting layers have a greater impact on the device performance, the charge generation layer plays a key role in the Tandem WOLED structure. A typical charge generation layer is a p-n junction double-layered structure composed of a P-type charge generation layer and an N-type charge generation layer. However, electron injection barrier of the charge generation layer from the N-type charge generation layer to the adjacent electron transport layer is relatively large, and thus the electrons accumulate on an interface between the N-type charge generation layer and the adjacent electron transport layer, which easily causes deterioration of the interface and shortens the service life of the device.

In order to make the objectives, technical solutions, and advantages of the embodiments of the present disclosure clearer, the technical solutions of the embodiments of the present disclosure will be described clearly and comprehensively with reference to the accompanying drawings of the embodiments of the present disclosure. Obviously, the described embodiments are part of the embodiments of the present disclosure rather than all of them. Based on the described embodiments of the present disclosure, all the other embodiments obtained by those skilled in the art without creative labor fall within the protection scope of the present disclosure.

Unless otherwise defined, the technical terms or scientific terms used herein shall have common meanings understood by those skilled in the art to which the present disclosure belongs. The terms “first”, “second” and the like used in the description and claims of the present disclosure do not indicate any sequence, quantity or importance, but are only used to distinguish different composite parts. The term “include” or “have” and the like mean that an element or item appearing therebefore covers elements or items listed thereafter and their equivalents, but do not exclude other elements or items. The terms “inner”, “outer”, “upper”, “lower” and the like are only used to indicate relative positional relationship, and when an absolute position of an object described changes, the relative positional relationship may also change accordingly.

The shape and size of each film layer shown in the drawings do not reflect its true ratio in the OLED, and only serve to illustrate the present disclosure schematically.

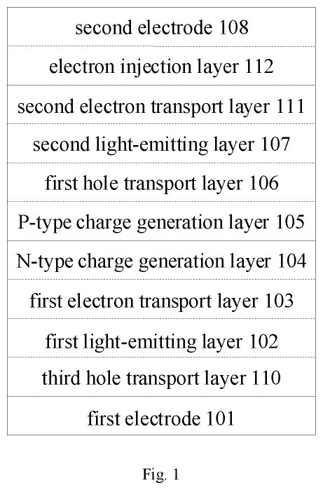

An OLED provided by embodiments of the present disclosure, as shown in FIGS. 1-4, includes a first electrode 101, a first light-emitting layer 102, a first electron transport layer 103, and an N-type charge generation Layer 104, a P-type charge generation layer 105, a first hole transport layer 106, a second light-emitting layer 107 and a second electrode 108 that are stacked;

where the N-type charge generation layer 104 includes a host electron transport material and a first guest electron transport material; and the host electron transport material and the first guest electron transport material have a set matching energy level therebetween.

In the OLED provided by the embodiments of the present disclosure, the N-type charge generation layer 104 includes the host electron transport material and the first guest electron transport material that have a set matching energy level therebetween, which can not only reduce electron injection barrier from the N-type charge generation layer 104 to the first electron transport layer 103 but also increase continuity of energy level arrangement in the N-type charge generation layer 104, increase positions of acceptable electrons, and effectively avoid an accumulation of the electrons on an interface between the N-type charge generation layer 104 and the first electron transport layer 103, thereby increasing the service life of the OLED.

In addition, due to the electron accumulation on the interface between the N-type charge generation layer 104 and the first electron transport layer 103, the electrons cannot be effectively transported to the first light-emitting layer 102, so that luminous brightness of the first light-emitting layer 102 and the second light-emitting layer 107 decays at an inconsistent rate. If the luminous colors of the first light-emitting layer 102 and the second light-emitting layer 107 are different, it is easy to cause the problem of color deviation. The OLED provided by the present disclosure is set to include the N-type charge generation layer 104 which includes the host electron transport material and the first guest electron transport material having a set matching energy level therebetween, which effectively reduces the electron injection barrier from the N-type charge generation layer 104 to the first electron transport layer 103, so that the electrons are transported to the first light-emitting layer 102 more easily and then combined with the holes from the first electrode 101 to emit light. Therefore, the problem on inconsistency of decay rates of luminous brightness of the first light-emitting layer 102 and the second light-emitting layer 107 is improved to some extent, and the phenomenon of color deviation is reduced or even avoided.

It should be noted that, in the OLED provided by the embodiment of the present disclosure, the N-type charge generation layer 104 generally further includes a metal material (e.g., Li, Mg, Ca, Cs, Yb); and the P-type charge generation layer 105 is usually made of a metal oxide (e.g., ITO, WO₃, MoO₃, V₂O₅, ReO₃), or a hole transport material doped with a Lewis acid (e.g., FeCl₃:NPB, F4-TCNQ:NPB), or a P-type organic material (e.g., HATCN).

In specific implementation, in order to block holes in the first light-emitting layer 102 and increase continuity of energy level arrangement in the N-type charge generation layer 104, in the OLED provided by the embodiment of the present disclosure, the HOMO value of either of the host electron transport material and the first guest electron transport material is less than or equal to −6.0 eV, and an absolute value of a difference between the LUMO value of the host electron transport material and the LUMO value of the first guest electron transport material is greater than or equal to 0.2 eV.

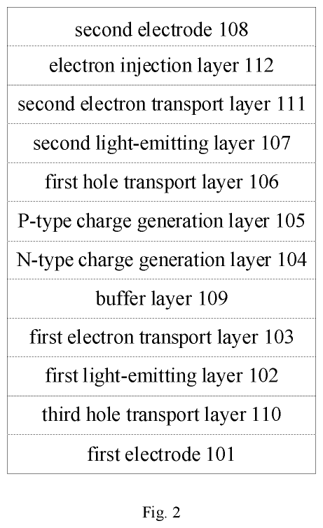

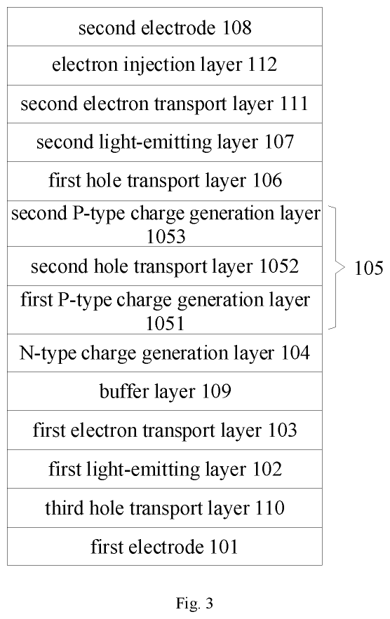

In specific implementation, in order to further reduce the electron injection barrier from the N-type charge generation layer 104 to the first electron transport layer 103, the OLED provided by the embodiment of the present disclosure, as shown in FIGS. 2 and 3, may further include a buffer layer 109 positioned between the N-type charge generation layer 104 and the first electron transport layer 103;

where the buffer layer 109 includes a second guest electron transport material.

Specifically, in order to make the electrons injected into the first electron transport layer 103 more easily to improve the service life of the OLED and the phenomenon of the color deviation, in the OLED provided by the embodiment of the present disclosure, the LUMO value of the second guest electron transport material is greater than or equal to the LUMO value of the host electron transport material and less than or equal to the LUMO value of the first electron transport layer 103; and a difference between the LUMO value of the first electron transport layer 103 and the LUMO value of the second guest electron transport material is less than or equal to 0.3 eV.

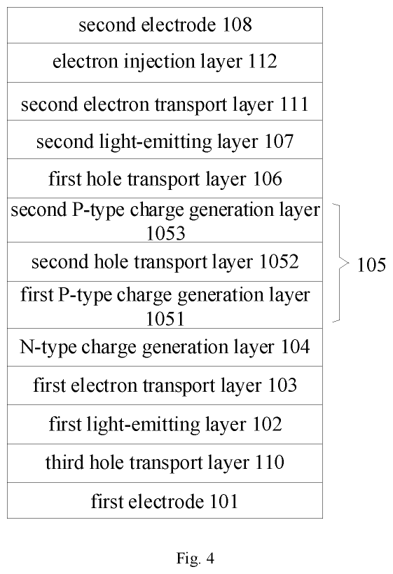

In specific implementation, there is some difficulty in injecting the holes from the P-type charge generation layer 105 into the first hole transport layer 106. Especially when the P-type charge generation layer 105 is composed of the hole transport material doped with the Lewis acid, the P-type charge generation layer 105 is doped at a high concentration and the vacuum energy level is bent more upwards, resulting in an increase in the potential barrier between the P-type charge generation layer 105 and the first hole transport layer 106. The difficulty in injecting the holes from the P-type charge generation layer 105 into the first hole transport layer 106 increases, the holes will thus accumulate on the interface between the P-type charge generation layer 105 and the first hole transport layer 106, which will deteriorate the interface and affect the service life of the OLED. Therefore, in order to reduce the potential barrier between the P-type charge generation layer 105 and the first hole transport layer 106 to facilitate hole injection and increase the service life of the OLED, in the OLED provided by the embodiment of the present disclosure, as shown in FIGS. 3 and 4, the P-type charge generation layer 105 may include a first P-type charge generation layer 1051, a second hole transport layer 1052 and a second P-type charge generation layer 1053 that are stacked; the first P-type charge generation layer 1051 and the N-type charge generation layer 104 are adjacent; and the second P-type charge generation layer 1053 and the first hole transport layer 106 are adjacent.

Specifically, in the OLED provided by the embodiment of the present disclosure, the first P-type charge generation layer 1051 includes a first hole transport material doped with a first Lewis acid;

a mass percent of the first Lewis acid in the first P-type charge generation layer 1051 is 5%-15%; and a higher doping concentration causes the energy level of the first P-type charge generation layer 1051 to be bent more, so that the energy level of the N-type charge generation layer may be well matched and charge separation may be effectively realized;

the second P-type charge generation layer 1053 includes a second hole transport material doped with a second Lewis acid;

a mass percent of the second Lewis acid in the second P-type charge generation layer 1053 is 1%-5%; and a lower doping concentration causes the energy level of the second P-type charge generation layer 1053 to be bent less, so that the energy level of the first hole transport layer 106 may be well matched and holes may be effectively injected from the second P-type charge generation layer 1053 to the first hole transport layer 106; and

an absolute value of an HOMO value of the second hole transport layer 1052 is less than or equal to 5.5 eV, so that the energy level matching between the second hole transport layer 1052 and the first P-type charge generation layer 1051 is better and thereby the holes may be easily injected from the first P-type charge generation layer 1051 to the second hole transport layer 1052.

It should be noted that the first hole transport material and the second hole transport material may be the same or different, which is not limited herein. The first Lewis acid and the second Lewis acid may be the same or different, which is not limited herein, either.

Optionally, in the OLED provided by the embodiment of the present disclosure, in order to reduce better the potential barrier between the P-type charge generation layer 105 and the first hole transport layer 106 to facilitate injection of the holes, the mass percent of the first Lewis acid in the first P-type charge generation layer 1051 is 10%;

the mass percent of the second Lewis acid in the second P-type charge generation layer 1053 is 3%; and

the absolute value of the HOMO value of the second hole transport layer 1052 is less than or equal to 5.3 eV.

In addition, because the holes accumulate on the interface between the P-type charge generation layer 105 and the first hole transport layer 106, the holes cannot be effectively transported to the second light-emitting layer 107, so that luminous brightness of the second light-emitting layer 107 and the first light-emitting layer 102 decays at an inconsistent rate. If the luminous colors of the first light-emitting layer 102 and the second light-emitting layer 107 are different, it is easy to cause the problem of color deviation. The OLED provided by the present disclosure is set to include the P-type charge generation layer 105 including the first P-type charge generation layer 1051, the second hole transport layer 1052 and the second P-type charge generation layer 1053 that are stacked, which effectively reduces the injection barrier of the holes from the P-type charge generation layer 105 to the first hole transport layer 106, so that the holes are transported to the second light-emitting layer 107 more easily and then combined with the electrons from the second electrode 108 to emit light. Therefore, the problem of inconsistency of decay rates of luminous brightness of the first light-emitting layer 102 and the second light-emitting layer 107 is improved to some extent, and the phenomenon of color deviation is reduced or even avoided.

In specific implementation, generally the OLED provided by the embodiment of the present disclosure, as shown in FIGS. 1-4, may further include a third hole transport layer 110, a second electron transport layer 111, and an electron injection layer 112.

It may be understood that, in the OLED provided by the embodiment of the present disclosure, in order to enable the OLED to realize the light-emitting function and improve the service life of the OLED, as shown in FIG. 1, the OLED may include the first electrode 101, the third hole transport layer 110, the first light-emitting layer 102, the first electron transport layer 103, the N-type charge generation layer 104, the P-type charge generation layer 105, the first hole transport layer 106, the second light-emitting layer 107 and the second electrode 108 that are stacked in sequence. The N-type charge generation layer 104 includes the host electron transport material and the first guest electron transport material; and the host electron transport material and the first guest electron transport material have a set matching energy level therebetween.

In addition, when the OLED further includes the buffer layer 109, as shown in FIG. 2, the OLED further includes the first electrode 101, the third hole transport layer 110, the first light emitting layer 102, the first electron transport layer 103, the buffer layer 109, the N-type charge generation layer 104, the P-type charge generation layer 105, the first hole transport layer 106, the second light-emitting layer 107, and the second electrode 108 that are stacked in sequence. The N-type charge generation layer 104 includes the host electron transport material and the first guest electron transport material; and the host electron transport material and the first guest electron transport material have a set matching energy level therebetween.

In addition, when the OLED further includes the buffer layer 109; and the P-type charge generation layer 105 includes the first P-type charge generation layer 1051, the second hole transport layer 1052 and the second P-type charge generation layer 1053 that are stacked, as shown in FIG. 3, the OLED may further include the first electrode 101, the third hole transport layer 110, the first light-emitting layer 102, the first electron transport layer 103, the buffer layer 109, the N-type charge generation layer 104, the first P-type charge generation layer 1051, the second hole transport layer 1052, the second P-type charge generation layer 1053, the first hole transport layer 106, the second light-emitting layer 107 and the second electrode 108 that are stacked in sequence. The N-type charge generation layer 104 includes the host electron transport material and the first guest electron transport material; and the host electron transport material and the first guest electron transport material have a set matching energy level therebetween.

Furthermore, when the P-type charge generation layer 105 includes the first P-type charge generation layer 1051, the second hole transport layer 1052 and the second P-type charge generation layer 1053 that are stacked, as shown in FIG. 4, the OLED may further include the first electrode 101, the third hole transport layer 110, the first light-emitting layer 102, the first electron transport layer 103, the N-type charge generation layer 104, the first P-type charge generation layer 1051, the second hole transport layer 1052, the second P-type charge generation layer 1053, the first hole transport layer 106, the second light-emitting layer 107 and the second electrode 108 that are stacked in sequence. The N-type charge generation layer 104 includes the host electron transport material and the first guest electron transport material; and the host electron transport material and the first guest electron transport material have a set matching energy level therebetween.

In specific implementation, in the OLED provided by the embodiment of the present disclosure, colors of light emitted by the first light-emitting layer 102 and the second light-emitting layer 107 may be the same or different, which is not limited herein. In addition, the first light-emitting layer 102 and the second light-emitting layer 107 may include one of blue dopants with blue fluorescence light-emitting characteristics, green dopants with green phosphorescence light-emitting characteristics, yellow-green dopants with yellow-green phosphorescence light-emitting characteristics, yellow dopants with yellow phosphorescence light-emitting characteristics and red dopants with red phosphorescence light-emitting characteristics or any combinations thereof, which is not limited herein.

Based on the same inventive concept, it is difficult to inject the holes from the P-type charge generation layer 105 into the first hole transport layer 106. Especially when the P-type charge generation layer 105 is composed of the hole transport material doped with the Lewis acid, the P-type charge generation layer 105 is doped at a high concentration, and the vacuum energy level is bent more upwards, resulting in an increase in the potential barrier between the P-type charge generation layer 105 and the first hole transport layer 106 and an increase in difficulty in injecting the holes from the P-type charge generation layer 105 into the first hole transport layer 106. The holes will thus accumulate on the interface from the P-type charge generation layer 105 to the first hole transport layer 106, which will deteriorate the interface and affect the service life of the OLED. Therefore, in order to reduce the potential barrier between the P-type charge generation layer 105 and the first hole transport layer 106 to facilitate injection of the holes and increase the service life of the OLED, an OLED is further provided by the embodiment of the present disclosure, as shown in FIG. 4, which includes the first electrode 101, the first light-emitting layer 102, the first electron transport layer 103, the N-type charge generation layer 104, the P-type charge generation layer 105, the first hole transport layer 106, the second light-emitting layer 107 and the second electrode 108 that are stacked;

where the P-type charge generation layer 105 includes the first P-type charge generation layer 1051, the second hole transport layer 1052 and the second P-type charge generation layer 1053 that are stacked; the first P-type charge generation layer 1051 and the N-type charge generation layer 104 are adjacent; and the second P-type charge generation layer 1053 and the first hole transport layer 106 are adjacent.

Specifically, in the OLED provided by the embodiment of the present disclosure, the first P-type charge generation layer 1051 includes the first hole transport material doped with the first Lewis acid;

the mass percent of the first Lewis acid in the first P-type charge generation layer 1051 is 5%-15%; and a higher doping concentration causes the energy level of the first P-type charge generation layer 1051 to be bent more, so that the energy level of the N-type charge generation layer may be well matched and charge separation may be effectively realized;

the second P-type charge generation layer 1053 includes the second hole transport material doped with the second Lewis acid;

the mass percent of the second Lewis acid in the second P-type charge generation layer 1053 is 1%-5%; and a lower doping concentration causes the energy level of the second P-type charge generation layer 1053 to be bent less, so that the energy level of the first hole transport layer 106 may be well matched and the holes may be effectively injected from the second P-type charge generation layer 1053 to the first hole transport layer 106; and

the absolute value of the HOMO value of the second hole transport layer 1052 is less than or equal to 5.5 eV, so that the energy level matching between the second hole transport layer 1052 and the first P-type charge generation layer 1051 is better and thereby the holes may be easily injected from the first P-type charge generation layer 1051 to the second hole transport layer 1052.

It should be noted that the first hole transport material and the second hole transport material may be the same or different, which is not limited herein. The first Lewis acid and the second Lewis acid may be the same or different, which is not limited herein.

Optionally, in the OLED provided by the embodiment of the present disclosure, in order to better reduce the potential barrier between the P-type charge generation layer 105 and the first hole transport layer 106 to facilitate injection of the holes, the mass percent of the first Lewis acid in the first P-type charge generation layer 1051 is 10%;

the mass percent of the second Lewis acid in the second P-type charge generation layer 1053 is 3%; and

the absolute value of the HOMO value of the second hole transport layer 1052 is less than or equal to 5.3 eV.

In specific implementation, generally the OLED provided by the embodiment of the present disclosure, as shown in FIG. 4, may further include the third hole transport layer 110, the second electron transport layer 111, and the electron injection layer 112.

It may be understood that, in the OLED provided by the embodiment of the present disclosure, in order to enable the OLED to realize the light-emitting function and to increase the service life of the OLED, the OLED may include the first electrode 101, the third hole transport layer 110, the first light-emitting layer 102, the first electron transport layer 103, the N-type charge generation layer 104, the first P-type charge generation layer 1051, the second hole transport layer 1052, the second P-type charge generation layer 1053, the first hole transport layer 106, the second light-emitting layer 107 and the second electrode 108 that are stacked in sequence. The composition of the N-type charge generation layer 104 is the same as that of the related art.

It may be understood that the above OLED provided by the embodiments of the present disclosure is a tandem OLED including two organic light-emitting layers, but in specific implementation, it may not be limited to a two-layer-stacked structure, a three-layer-stacked structure or a more-layer-stacked structure. In addition, the OLED may be a tandem WOLED, a tandem blue light OLED, or a tandem OLED of any combination of colors, which is not limited herein.

In order to better understand technical solutions of the OLEDs provided by the embodiments of the present disclosure, a set of comparative examples will be used to describe them in detail below.

This set of comparative examples includes an OLED in the related art and OLEDs of four structures provided by the embodiments of the present disclosure.

The OLED in the related art, as shown in FIG. 1, may specifically include the first electrode 101, the third hole transport layer 110, the first light-emitting layer 102, the first electron transport layer 103, the N-type charge generation layer 104, the P-type charge generation layer 105, the first hole transport layer 106, the second light-emitting layer 107, the second electron transport layer 111, the electron injection layer 112 and the second electrode 108 that are stacked in sequence; where the first light-emitting layer 102 includes a blue light dopant with blue fluorescence light-emitting characteristics, and the second light-emitting layer 107 includes a green light dopant with green phosphorescence light-emitting characteristics and a red light dopant with red phosphorescence light-emitting characteristics.

The OLED of the first structure provided by embodiments of the present disclosure is shown in FIG. 1. Since the OLED of the first structure provided by the embodiments of the present disclosure has a similar structure to the OLED in the related art, only the differences therebetween will be described below, and the repetitions are omitted herein. Specifically, the difference between the OLED of the first structure provided by the embodiments of the present disclosure and the OLED in the related art is that: the N-type charge generation layer 104 includes the host electron transport material and the first guest electron transport material; where the HOMO value of the host electron transport material is −6.1 eV and the LUMO value of the host electron transport material is −2.9 eV; the LUMO value of the first guest electron transport material is −2.7 eV; and an absolute value of a difference between the LUMO value of the host electron transport material and the LUMO value of the first guest electron transport material is equal to 0.2 eV.

The OLED of the second structure provided by the embodiments of the present disclosure is shown in FIG. 2. Since the OLED of the second structure provided by the embodiments of the present disclosure has a similar structure to the OLED of the first structure provided by the embodiments of the present disclosure, only the differences therebetween will be described below, and the repetitions are omitted herein. Specifically, the OLED of the second structure provided by the embodiments of the present disclosure differs from the OLED of the first structure provided by the embodiments of the present disclosure in that: the buffer layer 109, including the second guest electron transport material and positioned between the N-type charge generation layer 104 and the first electron transport layer 103, is also included. In addition, the LUMO value of the second guest electron transport material is −2.9 eV, the LUMO value of the first electron transport layer 103 is −2.7 eV, and a difference between the LUMO value of the first electron transport layer and the LUMO value of the second guest electron transport material is equal to 0.2 eV. In other words, the LUMO value (−2.9 eV) of the second guest electron transport material is greater than or equal to the LUMO value (−2.9 eV) of the host electron transport material and less than or equal to the LUMO value (−2.7 eV) of the first electron transport layer, and a difference between the LUMO value of the first electron transport layer and the LUMO value of the second guest electron transport material is less than or equal to 0.3 eV.

The OLED of the third structure provided by the embodiments of the present disclosure is shown in FIG. 4. Since the OLED of the third structure provided by the embodiments of the present disclosure has a similar structure to the OLED in the related art, only the differences therebetween will be described below, and the repetitions will be omitted herein. Specifically, the difference between the OLED of the third structure provided by the embodiments of the present disclosure and the OLED in the related art is that: the P-type charge generation layer 105 includes the first P-type charge generation layer 1051, the second hole transport layer 1052 and the second P-type charge generation layer 1053 stacked between the N-type charge generation layer 104 and the first hole transport layers 106. The first P-type charge generation layer 1051 includes the first hole transport material doped with the first Lewis acid, and the mass percent of the first Lewis acid in the first P-type charge generation layer 1051 is 10%; the second P-type charge generation layer 1053 includes the second hole transport material doped with the second Lewis acid, and the mass percent of the second Lewis acid in the second P-type charge generation layer is 3%; and the absolute value of the HOMO value of the second hole transport layer is equal to 5.3 eV.

The OLED of the fourth structure provided by the embodiments of the present disclosure is shown in FIG. 4. Since the OLED of the fourth structure provided by the embodiments of the present disclosure has a similar structure to the OLED of the third structure provided by the embodiments of the present disclosure, only the differences therebetween will be described below, and the repetitions are omitted herein. Specifically, the difference between the OLED of the fourth structure provided by the embodiments of the present disclosure and the OLED of the third structure provided by the embodiments of the present disclosure is that: the N-type charge generation layer 104 includes the host electron transport material and the first guest electron transport material; where the HOMO value of the host electron transport material is −6.1 eV, and the LUMO value of the host electron transport material is −2.9 eV; the LUMO value of the first guest electron transport material is −2.7 eV; and the absolute value of the difference between the LUMO value of the host electron transport material and the LUMO value of the first guest electron transport material is equal to 0.2 eV.

Table 1 shows relevant test data of the five types of OLEDs in the set of comparative examples. Specifically, A represents the OLED in the related art, B represents the OLED of the first structure provided by the embodiments of the present disclosure, C represents the OLED of the second structure provided by the embodiments of the present disclosure, D represents the OLED of the third structure provided by the embodiments of the present disclosure, and E represents the OLED of the fourth structure provided by the embodiments of the present disclosure.

It can be seen from Table 1 that the service life of the OLED in the related art is 100%, the service life of the OLED of the first structure provided by the embodiments of the present disclosure is 380%, the service life of the OLED of the second structure provided by the embodiments of the present disclosure is 570%, the service life of the OLED of the third structure provided by the embodiments of the present disclosure is 450%, and the service life of the OLED of the fourth structure provided by the embodiments of the present disclosure is 585%. Therefore, compared with the OLED in the related art, the service lives of the OLEDs of the four structures provided by the embodiments of the present disclosure are greatly improved. In addition, as can be seen further from the comparison, compared with the OLED in the related art, the OLEDs provided by the embodiments of the present disclosure have a reduced lighting voltage, improved current efficiency and external quantum efficiency, and an improved device performance.

TABLE 1

| | Current | Lighting | Current | External quantum | |
|---|---|---|---|---|---|
| | density J | voltage | efficiency | efficiency | Service |
| Type | (mA/cm²) | V (V) | C.E.(cd/A) | EQE (%) | life |
| A | 10 | 8.8 | 34.8 | 17.2 | 100% |
| B | 10 | 8.6 | 35.5 | 19.4 | 380% |
| C | 10 | 8.4 | 39.8 | 22.7 | 570% |
| D | 10 | 8.5 | 36.1 | 19.7 | 450% |
| E | 10 | 8.2 | 40.8 | 23.2 | 585% |

Based on the same inventive concept, embodiments of the present disclosure further provide a display panel including the OLED provided by this embodiment. Since the principle of solving problems by the display panel is similar to the principle of solving the problem by the OLED, the embodiments of the OLEDs may be referred to for implementation of the display panel, and the repetitions will be omitted herein.

Based on the same inventive concept, the embodiments of the present disclosure further provide a display device including the OLED provided by this embodiment, and the display device may be a mobile phone, a tablet computer, a television, a monitor, a notebook computer, a digital photo frame, a navigator, a smart watch, a fitness wristband, a personal digital assistant, and any other products or components with display functions. Since the principle of solving problems by the display device is similar to the principle of solving problems by the OLED, the embodiments of the OLEDs may be referred to for implementation of the display device, and the repetitions will be omitted herein.

The OLED, the display panel and the display device provided by the embodiments of the present disclosure include the first electrode, the first light-emitting layer, the first electron transport layer, the N-type charge generation layer, the P-type charge generation layer, the first hole transport layer, the second light-emitting layer and the second electrode that are stacked in sequence; where the N-type charge generation layer includes the host electron transport material and the first guest electron transport material, and the host electron transport material and the first guest electron transport material have a set matching energy level therebetween. The N-type charge generation layer includes the host electron transport material and the first guest electron transport material that have a set matching energy level therebetween, which can not only reduce the electron injection barrier from the N-type charge generation layer to the first electron transport layer but also increase continuity of energy level arrangement in the N-type charge generation layer and increase positions of acceptable electrons, thereby effectively avoiding the accumulation of the electrons on an interface between the N-type charge generation layer and the first electron transport layer and improving the service life of the OLED.

It is apparent that those skilled in the art may make various variations and modifications to the present disclosure without departing from the spirit and scope of the present disclosure. In this way, if these modifications and variations to the present disclosure fall within the scope of the claims of the present disclosure and their equivalents, the present disclosure is also intended to include these modifications and variations.

1. An organic electroluminescent device (OLED), comprising:
a first electrode, a first light-emitting layer, a first electron transport layer, an N-type charge generation layer, a P-type charge generation layer, a first hole transport layer, a second light-emitting layer and a second electrode that are stacked;
wherein the N-type charge generation layer comprises a host electron transport material and a first guest electron transport material; and
the host electron transport material and the first guest electron transport material have a set matching energy level therebetween.

2. The OLED according to claim 1, wherein an HOMO value of either of the host electron transport material and the first guest electron transport material is less than or equal to −6.0 eV; and
an absolute value of a difference between an LUMO value of the host electron transport material and an LUMO value of the first guest electron transport material is greater than or equal to 0.2 eV.

3. The OLED according to claim 1, further comprising: a buffer layer positioned between the N-type charge generation layer and the first electron transport layer;
wherein the buffer layer comprises a second guest electron transport material.

4. The OLED according to claim 3, wherein an LUMO value of the second guest electron transport material is greater than or equal to the LUMO value of the host electron transport material and less than or equal to an LUMO value of the first electron transport layer; and
a difference between the LUMO value of the first electron transport layer and the LUMO value of the second guest electron transport material is less than or equal to 0.3 eV.

5. The OLED according to claim 1, wherein, the P-type charge generation layer comprises a first P-type charge generation layer, a second hole transport layer and a second P-type charge generation layer that are stacked;
the first P-type charge generation layer and the N-type charge generation layer are adjacent; and
the second P-type charge generation layer and the first hole transport layer are adjacent.

6. The OLED according to claim 5, wherein, the first P-type charge generation layer comprises a first hole transport material doped with a first Lewis acid, and a mass percent of the first Lewis acid in the first P-type charge generation layer is 5%-15%;
the second P-type charge generation layer comprises a second hole transport material doped with a second Lewis acid, and a mass percent of the second Lewis acid in the second P-type charge generation layer is 1%-5%; and
an absolute value of an HOMO value of the second hole transport layer is less than or equal to 5.5 eV.

7. The OLED according to claim 6, wherein, the mass percent of the first Lewis acid in the first P-type charge generation layer is 10%;
the mass percent of the second Lewis acid in the second P-type charge generation layer is 3%; and
the absolute value of the HOMO value of the second hole transport layer is less than or equal to 5.3 eV.

8. The OLED according to claim 1, further comprising a third hole transport layer, a second electron transport layer and an electron injection layer;
wherein the first electrode, the third hole transport layer, the first light-emitting layer, the first electron transport layer, the N-type charge generation layer, the P-type charge generation layer, the first hole transport layer, the second light-emitting layer, the second electron transport layer, the electron injection layer and the second electrode are stacked in sequence.

9. The OLED according to claim 3, further comprising a third hole transport layer, a second electron transport layer and an electron injection layer;
wherein the first electrode, the third hole transport layer, the first light-emitting layer, the first electron transport layer, the buffer layer, the N-type charge generation layer, the P-type charge generation layer, the first hole transport layer, the second light-emitting layer, the second electron transport layer, the electron injection layer and the second electrode are stacked in sequence.

10. The OLED according to claim 5, further comprising a third hole transport layer, a second electron transport layer and an electron injection layer;
wherein the first electrode, the third hole transport layer, the first light-emitting layer, the first electron transport layer, the N-type charge generation layer, the first P-type charge generation layer, the second hole transport layer, the second P-type charge generation layer, the first hole transport layer, the second light-emitting layer, the second electron transport layer, the electron injection layer and the second electrode are stacked in sequence; or
the first electrode, the third hole transport layer, the first light-emitting layer, the first electron transport layer, the buffer layer, the N-type charge generation layer, the first P-type charge generation layer, the second hole transport layer, the second P-type charge generation layer, the first hole transport layer, the second light-emitting layer, the second electron transport layer, the electron injection layer and the second electrode are stacked in sequence.

11. The OLED according claim 1, wherein the first light-emitting layer and the second light-emitting layer emit light with a same color or different colors.

12. An organic electroluminescent device (OLED), comprising a first electrode, a first light-emitting layer, a first electron transport layer, an N-type charge generation layer, a P-type charge generation layer, a first hole transport layer, a second light-emitting layer and a second electrode that are stacked;
wherein the P-type charge generation layer comprises a first P-type charge generation layer, a second hole transport layer and a second P-type charge generation layer that are stacked;
the first P-type charge generation layer and the N-type charge generation layer are adjacent; and
the second P-type charge generation layer and the first hole transport layer are adjacent.

13. The OLED according to claim 12, wherein, the first P-type charge generation layer comprises a first hole transport material doped with a first Lewis acid, and a mass percent of the first Lewis acid in the first P-type charge generation layer is 5%-15%;
the second P-type charge generation layer comprises a second hole transport material doped with a second Lewis acid, and a mass percent of the second Lewis acid in the second P-type charge generation layer is 1%-5%; and
an absolute value of an HOMO value of the second hole transport layer is less than or equal to 5.5 eV.

14. The OLED according to claim 13, wherein, the mass percent of the first Lewis acid in the first P-type charge generation layer is 10%;
the mass percent of the second Lewis acid in the second P-type charge generation layer is 3%; and
the absolute value of the HOMO value of the second hole transport layer is less than or equal to 5.3 eV.

15. The OLED according to claim 12, further comprising a third hole transport layer, a second electron transport layer and an electron injection layer;
wherein the first electrode, the third hole transport layer, the first light-emitting layer, the first electron transport layer, the N-type charge generation layer, the first P-type charge generation layer, the second hole transport layer, the second P-type charge generation layer, the first hole transport layer, the second light-emitting layer, the second electron transport layer, the electron injection layer and the second electrode are stacked in sequence.

16. A display panel, comprising the OLED according to claim 1.

17. A display device, comprising the display panel according to claim 16.
